(19) United States
(12) Patent Application Publication
(10) Pub. No.: US 2024/0347557 A1
(43) Pub. Date: Oct. 17, 2024

(54) IMAGING DEVICE

(71) Applicant: SONY SEMICONDUCTOR SOLUTIONS CORPORATION, Kanagawa (JP)

(72) Inventors: Koji MIYATA, Kanagawa (JP); Atsushi TODA, Kanagawa (JP)

(73) Assignee: SONY SEMICONDUCTOR SOLUTIONS CORPORATION, Kanagawa (JP)

(21) Appl. No.: 18/292,492

(22) PCT Filed: Jul. 19, 2022
(86) PCT No.: PCT/JP2022/027989

§ 371 Date: Jan. 26, 2024

(30) Foreign Application Priority Data
Aug. 6, 2021 (JP) 2021-129693

(51) Int. Cl. H01L 27/146

(52) U.S. Cl. CPC H01L 27/14605; H01L 27/14621; H01L 27/14625; H01L 27/14652

(57) ABSTRACT

An imaging device according to an embodiment of the present disclosure includes: a first pixel, a second pixel, and a spectroscopic section. The first pixel includes a first photoelectric conversion section that selectively receives first wavelength light included in a first wavelength band and performs photoelectric conversion of the first wavelength light. The second pixel includes a second photoelectric conversion section that selectively receives second wavelength light included in a second wavelength band and performs photoelectric conversion of the second wavelength band. The second pixel is adjacent to the first pixel. The spectroscopic section includes a structure having a size less than or equal to a wavelength of incident light, and is provided on a boundary between the first pixel and the second pixel. The spectroscopic section separates the first wavelength light and the second wavelength light from the incident light.

### TECHNICAL FIELD

The present disclosure relates to an imaging device.

### BACKGROUND ART

There has been proposed an imaging device that uses a spectroscopic element including a plurality of pillar-shaped structures to obtain signals corresponding to color components (PTL 1).

### CITATION LIST

### Patent Literature

PTL 1: Japanese Unexamined Patent Application Publication No. 2020-123964

### SUMMARY OF THE INVENTION

The imaging device is desired to collect incident light efficiently.

It is desired to provide an imaging device that is able to collect light efficiently.

An imaging device according to an embodiment of the present disclosure includes a first pixel, a second pixel, and a spectroscopic section. The first pixel includes a first photoelectric conversion section that selectively receives first wavelength light included in a first wavelength band and performs photoelectric conversion of the first wavelength light. The second pixel includes a second photoelectric conversion section that selectively receives second wavelength light included in a second wavelength band and performs photoelectric conversion of the second wavelength light. The second pixel is adjacent to the first pixel, and the spectroscopic section includes a structure having a size less than or equal to a wavelength of incident light. The spectroscopic section is provided on a boundary between the first pixel and the second pixel, and separates the first wavelength light and the second wavelength light from the incident light.

### BRIEF DESCRIPTION OF DRAWING

FIG. 1 is a block diagram illustrating an example of an overall configuration of an imaging device according to a first embodiment of the present disclosure.

FIG. 2 is a diagram illustrating an example of a planar configuration of the imaging device according to the first embodiment of the present disclosure.

FIG. 3 is a diagram illustrating an example of a planar configuration of a portion of the imaging device according to the first embodiment of the present disclosure.

FIG. 4 is a block diagram illustrating an example of a cross-sectional configuration of the imaging device according to the first embodiment of the present disclosure.

FIG. 5 is a block diagram illustrating an example of a cross-sectional configuration of the imaging device according to the first embodiment of the present disclosure.

FIG. 6 is a diagram illustrating an example of a cross-sectional configuration of an imaging device according to a first modification of the present disclosure.

FIG. 7 is a diagram illustrating another example of the cross-sectional configuration of the imaging device according to the first modification of the present disclosure.

FIG. 8A is a diagram illustrating an example of a planar configuration of an imaging device according to a second modification of the present disclosure.

FIG. 8B is a diagram illustrating another example of the planar configuration of the imaging device according to the second modification of the present disclosure.

FIG. 9A is a diagram illustrating an example of a planar configuration of an imaging device according to a third modification of the present disclosure.

FIG. 9B is a diagram illustrating an example of the planar configuration of the imaging device according to the third modification of the present disclosure.

FIG. 10 is a diagram illustrating an example of a cross-sectional configuration of the imaging device according to the third modification of the present disclosure.

FIG. 11 is a diagram illustrating an example of a planar configuration of an imaging device according to a second embodiment of the present disclosure.

FIG. 12 is a block diagram illustrating an example of a cross-sectional configuration of the imaging device according to the second embodiment of the present disclosure.

FIG. 13 is a diagram illustrating an example of a cross-sectional configuration of an imaging device according to a fourth modification of the present disclosure.

FIG. 14 is a diagram illustrating an example of a planar configuration of an imaging device according to a fifth modification of the present disclosure.

FIG. 15 is a diagram illustrating another example of the planar configuration of the imaging device according to the fifth modification of the present disclosure.

FIG. 16 is a diagram illustrating an example of a planar configuration of an imaging device according to a sixth modification of the present disclosure.

FIG. 17 is a diagram illustrating another example of the planar configuration of the imaging device according to the sixth modification of the present disclosure.

FIG. 18 is a diagram illustrating an example of a planar configuration of an imaging device according to a seventh modification of the present disclosure.

FIG. 19 is a diagram illustrating an example of a cross-sectional configuration of the imaging device according to the seventh modification of the present disclosure.

FIG. 20 is a block diagram illustrating a configuration example of an electronic apparatus including the imaging device.

FIG. 21 is a block diagram depicting an example of schematic configuration of a vehicle control system.

FIG. 22 is a diagram of assistance in explaining an example of installation positions of an outside-vehicle information detecting section and an imaging section.

FIG. 23 is a view depicting an example of a schematic configuration of an endoscopic surgery system.

FIG. 24 is a block diagram depicting an example of a functional configuration of a camera head and a camera control unit (CCU).

### MODES FOR CARRYING OUT THE INVENTION

Next, with reference to drawings, details of embodiments of the present disclosure will be described. It is to be noted that the description will be given in the following order.
1. First Embodiment
2. Second Embodiment
3. Application Example
4. Further Application Example

### 1. First Embodiment

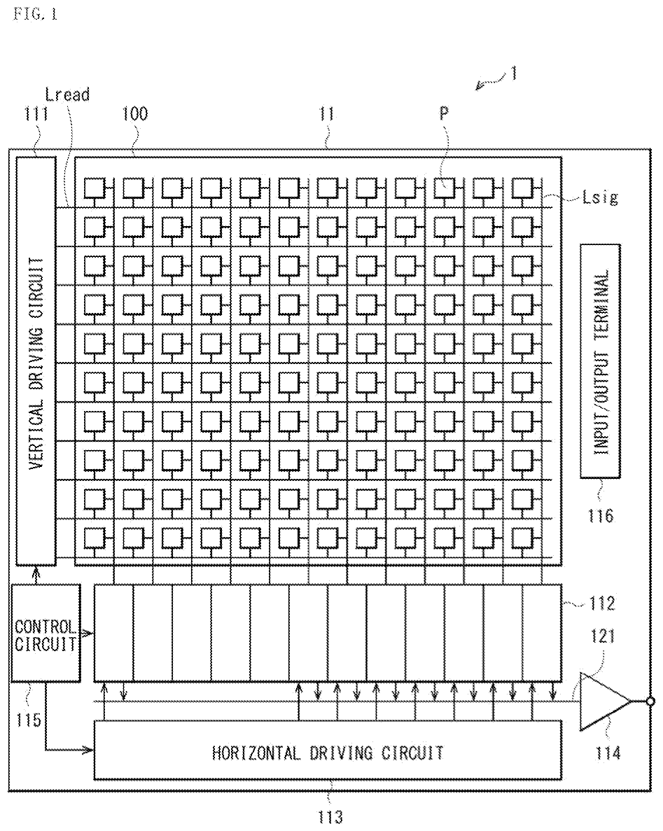

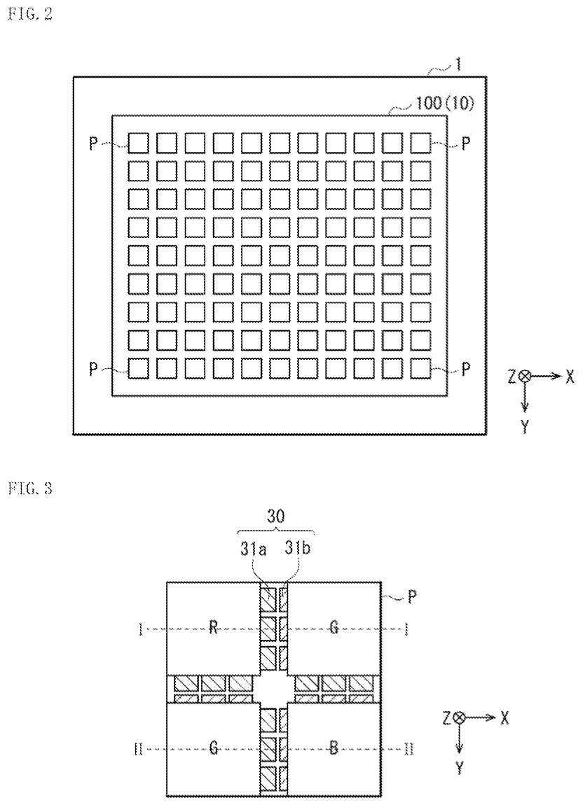

FIG. 1 is a block diagram illustrating an example of an overall configuration of an imaging device (imaging device 1) according to a first embodiment of the present disclosure. FIG. 2 is a diagram illustrating an example of a planar configuration of the imaging device 1. For example, the imaging device 1 is a complementary metal-oxide-semiconductor (CMOS) image sensor.

The imaging device 1 includes pixels P arranged in a matrix form. Each of the pixels includes a photoelectric conversion section. As illustrated in FIG. 2, the imaging device 1 includes an imaging area that is a region (pixel section 100) where the plurality of pixels P is two-dimensionally arranged in the matrix form. The imaging device 1 is applicable to an electronic apparatus such as a digital still camera or a video camera. As illustrated in FIG. 2, it is to be noted that a Z-axis direction is an incident direction of light from a subject, an X-axis direction is a left-right direction that is orthogonal to the Z-axis direction on the paper surface, and a Y-axis direction is a top-bottom direction that is orthogonal to the Z-axis and the X-axis on the paper surface. With regard to subsequent drawings, sometimes directions may be described on the basis of the directions of the arrows illustrated in FIG. 2.

### [Schematic Configuration of Imaging Device]

The imaging device 1 takes in incident light (image light) from the subject via an optical lens system. The imaging device 1 captures an image of the subject. The imaging device 1 converts an amount of the incident light that is formed as the image on an imaging surface into electric signals in units of pixels, and outputs the electric signals as pixel signals. The imaging device 1 includes the pixel section 100 as the imaging area. In addition, for example, the imaging device 1 includes a vertical driving circuit 111, column signal processing circuits 112, a horizontal driving circuit 113, an output circuit 114, a control circuit 115, an input/output terminal 116, and the like in a region around the pixel section 100.

The pixel section 100 includes the plurality of pixels P that is two-dimensionally arranged in the matrix form. The pixel section 100 has, for example, a plurality of pixel rows each including a plurality of pixels P arranged in a horizontal direction (a lateral direction of a paper surface) and a plurality of pixel columns each including a plurality of pixels P arranged in a vertical direction (a longitudinal direction of the paper surface).

In the pixel section 100, for example, one pixel drive line Lread (a row selection line and a reset control line) is wired with each pixel row, and one vertical signal line Lsig is wired with each pixel column. The pixel drive line Lread transmits a drive signal for signal reading from each pixel. The pixel drive line Lread has one end coupled to a corresponding output terminal, corresponding to the respective pixel rows, of the vertical driving circuit 111.

The vertical driving circuit 111 includes a shift register, an address decoder, and the like. The vertical driving circuit 111 is a pixel driving section that drives the respective pixels P in the pixel section 100 in units of rows, for example. The column signal processing circuit 112 includes an amplifier, a horizontal selection switch, and the like provided for each of the vertical signal lines Lsig. A signal outputted from each of the pixels Pin a pixel row selected and scanned by the vertical driving circuit 111 is supplied to the column signal processing circuit 112 through the vertical signal lines Lsig.

The horizontal driving circuit 113 includes a shift register, an address decoder, and the like, and drives respective horizontal selection switches of the column signal processing circuits 112 in sequence while scanning the respective horizontal selection switches. Such selective scanning by the horizontal driving circuit 113 causes the signals of the respective pixels P transmitted through the respective vertical signal lines Lsig to be outputted in sequence to a horizontal signal line 121 and be transmitted to outside of a semiconductor substrate 11 through the horizontal signal line 121.

The output circuit 114 performs signal processing on the signals supplied in sequence from the respective column signal processing circuits 112 through the horizontal signal line 121, and outputs the processed signals. The output circuit 114 may perform, for example, only buffering, or may perform black level adjustment, column variation correction, various kinds of digital signal processing, and the like.

Circuit components including the vertical driving circuit 111, the column signal processing circuit 112, the horizontal driving circuit 113, the horizontal signal line 121, and the output circuit 114 may be formed on the semiconductor substrate 11, or may be provided in an external control IC. Alternatively, these circuit components may be formed on different substrates coupled by a cable, or the like.

The control circuit 115 receives a clock given from the outside of the semiconductor substrate 11, or data or the like for instructing on operation modes, and also outputs data such as internal information of the imaging device 1. The control circuit 115 further includes a timing generator that generates various timing signals, and controls driving of peripheral circuits such as the vertical driving circuit 111, the column signal processing circuit 112, and the horizontal driving circuit 113, on the basis of the various timing signals generated by the timing generator. The input/output terminal 116 exchanges signals with the outside.

### [Configuration of Pixel]

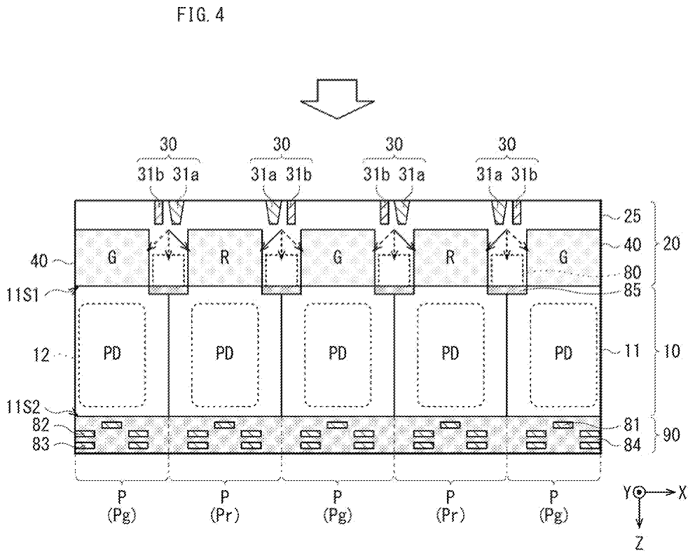

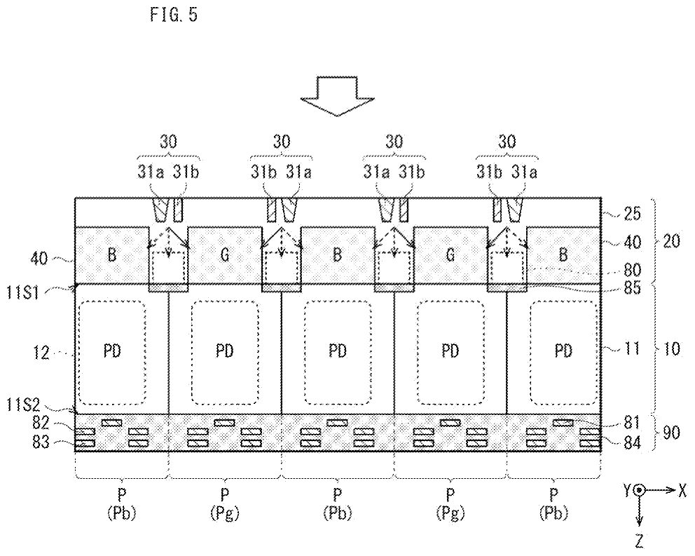

FIG. 3 is a diagram illustrating an example of a planar configuration of the imaging device 1. FIG. 4 illustrates an example of a cross-sectional configuration taken along a line I-I illustrated in FIG. 3. FIG. 5 illustrates an example of a cross-sectional configuration taken along a line II-II illustrated in FIG. 3. As illustrated in FIG. 4 and FIG. 5, the imaging device 1 is configured in such a manner that a light-receiving section 10, a light guiding section 20, and a multilayer wiring layer 90 are stacked, for example.

The light-receiving section 10 includes the semiconductor substrate 11 having a first surface 11S1 and a second surface 11S2 that are opposed to each other. The light guiding section 20 is provided on a side of the first surface 11A1 of the semiconductor substrate 11. The multilayer wiring layer 90 is provided on a side of the second surface 11S2 of the semiconductor substrate 11. It can also be said that, the light guiding section 20 is provided on a side where light from the optical lens system enters, and the multilayer wiring layer 90 is provided on an opposite side from the light incident side. The imaging device 1 is a so-called back-illuminated imaging device.

The semiconductor substrate 11 includes a silicon substrate, for example. The photoelectric conversion section 12 is, for example, a photodiode (PD), and includes a pn junction in a predetermined region of the semiconductor substrate 11. A plurality of the photoelectric conversion sections 12 is buried in the semiconductor substrate 11. The light-receiving section 10 includes the plurality of photoelectric conversion sections 12 provided along the first surface 11S1 and the second surface 11S2 of the semiconductor substrate 11.

The multilayer wiring layer 90 is configured in such a manner that a plurality of wiring layers 81, 82, and 83 are stacked with an interlayer insulating layer 84 interposed therebetween. A circuit (such as a transmission transistor, a reset transistor, or an amplification transistor, for example) for reading out the pixel signal based on electric charge generated by the photoelectric conversion section 12 is formed on the semiconductor substrate 11 and the multilayer wiring layer 90. In addition, for example, the above-described vertical driving circuit 111, column signal processing circuits 112, horizontal driving circuit 113, output circuit 114, control circuit 116, input/output terminal 116, and the like may be formed on the semiconductor substrate 11 and the multilayer wiring layer 90.

The wiring layers 81, 82, and 83 are formed by using aluminum (Al), copper (Cu), tungsten (W), or the like, for example. Alternatively, the wiring layers 81, 82, and 83 may be formed by using polysilicon (poly-Si). The interlayer insulating layer 84 includes a monolayer film containing one selected from the group consisting of, for example, silicon oxide (SiOx), TEOS, silicon nitride (SiNx), silicon oxynitride (SiOxNy), and the like, or alternatively, the interlayer insulating layer 84 includes a stacked film containing at least two selected therefrom.

The light guiding section 20 includes a transparent layer 25, a spectroscopic section 30, and a color filter 40, and guides incident light toward the light-receiving section 10. The transparent layer 25 is a transparent layer that transmits light, and includes material having a low refractive index such as silicon oxide (SiOx) or silicon nitride (SiNx). The spectroscopic section 30 and the color filter 40 are stacked above the light-receiving section 10 in a thickness direction orthogonal to the first surface 11S1 of the semiconductor substrate 11.

The imaging device 1 includes pixels Pr, pixels Pg, and pixels Pb. The color filter 40 selectively transmits light of a specific wavelength band among the incident light. Specifically, the pixel Pr includes a color filter 40 that transmits red light (R), the pixel Pg includes a color filter 40 that transmits green light (G), and the pixel Pb includes a color filter 40 that transmits blue light (B). The pixel section 100 of the imaging device 1 includes the pixels Pr, pixels Pg, and pixels Pb that are arranged on the basis of Bayer arrangement. The pixel Pr generates a pixel signal of R component, the pixel Pg generates a pixel signal of a G component, and the pixel Pb generates a pixel signal of a B component. The imaging device 1 is able to obtain the pixel signals of R, G, and B. It is to be noted that the color filters 40 are not limited to the primary color filters (RGB), but may be complementary color filters such as cyan (Cy), magenta (Mg), and yellow (Ye). In addition, it is also possible to provide a color filter corresponding to white (W), that is, a filter that transmits light of all wavelength bands among the incident light.

A waveguide 80 and a light shielding section 85 are provided on a boundary between adjacent pixels P. The light shielding section 85 blocks light. The waveguide 80 is a light guiding section and guides incident light to the light shielding section 85. The light shielding section 85 includes light-absorbing material and absorbs incident light. It is to be noted that the imaging device 1 may include a lens section (on-chip lens) that collects light. The lens section may be provided on a light incident side such as above the spectroscopic section 30.

The spectroscopic section 30 includes one or a plurality of structures 31, and disperses incident light. The structure 31 is a fine (micro) structure having a size less than or equal to a predetermined wavelength of the incident light. It is to be noted that FIG. 3 to FIG. 5 illustrate a first structure 31a and a second structure 31b as examples of the structure 31. In this specification, sometimes the first structure 31a and the second structure 31b may be collectively referred to as the structures 31. For example, the structure 31 has a size that is less than or equal to a visible wavelength. The spectroscopic section 30 is provided between the adjacent pixels P. The spectroscopic section 30 is positioned above the waveguide (light guiding section) 80 and the light shielding section 85. In FIG. 4, a spectroscopic section 30 is provided on a boundary between a pixel Pr and a pixel Pb that are adjacent to each other. In FIG. 5, a spectroscopic section 30 is provided on a boundary between a pixel Pg and a pixel Pb that are adjacent to each other.

The structure 31 has a refractive index that is higher than a refractive index of its surrounding medium. Examples of the surrounding medium around the structure 31 include silicon oxide (SiOx), air (atmosphere), and the like. In the present embodiment, the structure 31 includes material having a refractive index that is higher than a refractive index of the transparent layer 25. For example, the structure 31 may be formed by using silicon nitride (SiNx).

The spectroscopic section 30 causes phase delay of incident light and affects wavefronts due to a difference between the refractive index of the structure 31 and the refractive index of the surrounding medium. The spectroscopic section 30 changes a light propagation direction for each wavelength band due to different phase delay amounts depending on wavelengths of light. The spectroscopic section 30 therefore is able to separate the incident light into respective wavelength bands. The spectroscopic section 30 is a spectroscopic element that disperses light by using a metamaterial (metasurface) technology. The spectroscopic section 30 can be said as a region (spectroscopic region) where the incident light is dispersed by the structures 31.

As described above, for example, the spectroscopic section 30 includes the first structure 31a and the second structure 31b. Each of the first structure 31a and the second structure 31b is a pillar-shaped structure and is provided in the transparent layer 25. The first structure 31a and the second structure 31b are arranged side by side with a portion of the transparent layer 25 interposed therebetween in the left-right direction (X-axis direction) on the paper surface. The first structure 31a and the second structure 31b may be arranged at an interval that is less than or equal to a predetermined wavelength of incident light, such as the visible wavelength. In the example illustrated in FIG. 3, the spectroscopic section 30 includes a plurality of the first structures 31a and a plurality of the second structures 31b that surround the color filters 40.

The first structure 31a has a different size, shape, refractive index, or the like from those of the second structure 31b. In the example illustrated in FIG. 3 to FIG. 5, the size of the first structure 31a is different from the size of the second structure 31b. This allows the spectroscopic section 30 to cause the phase delay in such a manner that the incident light has different phase delays among the first to third wavelength bands, and this makes it possible to separate the incident light into light of the first wavelength band, light of the second wavelength band, and light of the third wavelength band.

The sizes, shapes, refractive indices, and the like of the respective structures 31 are decided in such a manner that the incident light is branched into light beams of the respective wavelength bands and the light beams travels to desired directions. It is possible to adjust phase differences between light traveling through the first structure 31a and light traveling through the second structure 31b for respective wavelength bands, and cause light beams of the respective wavelength bands incident on the spectroscopic section 30 to travel to different directions. For example, it is assumed that a width of the first structure 31a in the X-axis direction is wider than a width of the second structure 31b in the X-axis direction. As illustrated in FIG. 4, between the pixel Pr and the pixel Pg arranged in the X-axis direction, the first structure 31a is provided on a side near the pixel Pr, and the second structure 31b is provided on a side near the pixel Pg.

In this case, as schematically illustrated in FIG. 4, light of a green (G) wavelength band among the light incident on the spectroscopic section 30 travels from the spectroscopic section 30 toward a green (G) color filter 40. In addition, light of a red (R) wavelength band among the light incident on the spectroscopic section 30 travels from the spectroscopic section 30 toward a red (R) color filter 40. In addition, light of a blue (B) wavelength band among the light incident on the spectroscopic section 30 travels from the spectroscopic section 30 toward the light shielding section 85 through the waveguide 80.

The spectroscopic section 30 provided between the pixel Pr and the pixel Pg is able to propagate the green (G) light to a color filter 40 and a photoelectric conversion section 12 of the pixel Pg, and propagate the red (R) light to a color filter 40 and a photoelectric conversion section 12 of the pixel Pr. In addition, the spectroscopic section 30 provided between the pixel Pr and the pixel Pg is able to propagate the blue (B) light to the waveguide 80 and the light shielding section 85.

As illustrated in FIG. 5, between the pixel Pg and the pixel Pb arranged in the X-axis direction, the first structure 31a is provided on a side near the pixel Pb, and the second structure 31b is provided on a side near the pixel Pg. In this case, as schematically illustrated in FIG. 5, light of the green (G) wavelength band among the light incident on the spectroscopic section 30 travels from the spectroscopic section 30 toward the green (G) color filter 40. In addition, light of the blue (B) wavelength band among the light incident on the spectroscopic section 30 travels from the spectroscopic section 30 toward the blue (B) color filter 40. Light of the red (R) wavelength band among the light incident on the spectroscopic section 30 travels from the spectroscopic section 30 toward the light shielding section 85 through the waveguide 80.

The spectroscopic section 30 provided between the pixel Pg and the pixel Pb is able to propagate the green (G) light to a color filter 40 and a photoelectric conversion section 12 of the pixel Pg, and propagate the blue (B) light to a color filter 40 and a photoelectric conversion section 12 of the pixel Pb. In addition, the spectroscopic section 30 provided between the pixel Pg and the pixel Pb is able to propagate the red (R) light to the waveguide 80 and the light shielding section 85.

It is to be noted that a height (length) of the first structure 31a in the Z-axis direction may be higher (longer) than a height of the second structure 31b in the Z-axis direction. In addition, material of the first structure 31a may be different from material of the second structure 31b.

### Actions and Effects

The imaging device 1 according to the present embodiment includes the pixels P and the spectroscopic sections 30. The pixels P each include the photoelectric conversion section 12. The spectroscopic sections 30 each have a size less than or equal to a wavelength of incident light. A first pixel (such as the pixel Pr) includes a photoelectric conversion section 12 that selectively receives and performs photoelectric conversion on first wavelength light (red (R) light) included in the first wavelength band. A second pixel (such as the pixel Pg) includes a photoelectric conversion section 12 that selectively receives and performs photoelectric conversion on second wavelength light (green (G) light) included in the second wavelength band, the second pixel being adjacent to the first pixel. The spectroscopic section 30 is provided on a boundary between the first pixel and the second pixel, the spectroscopic section separating the first wavelength light and the second wavelength light from the incident light.

The imaging device 1 uses the spectroscopic section 30 provided on the boundary between the adjacent pixels P, to disperse light. This makes it possible to efficiently collect light beams of the respective wavelength bands incident on a gap between the adjacent pixels P onto the respective photoelectric conversion sections 12 of the pixel Pr, pixel Pg, and pixel Pb. It becomes possible to improve efficiency of collecting light and sensitivity to the incident light. In addition, by guiding unnecessary light toward the light shielding section 85, it is possible to suppress unnecessary light leaking to the surrounding photoelectric conversion section 12 and the like, and suppress color mixing.

Next, modifications of the present disclosure will be described. Hereinafter, structural elements that are similar to the above-described embodiment will be denoted with the same reference signs as the above-described embodiment, and repeated description will be omitted appropriately.

### (1-1. First Modification)

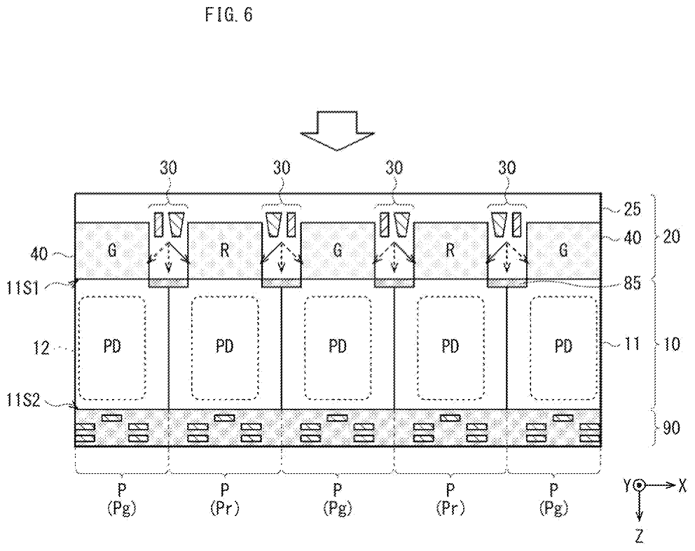

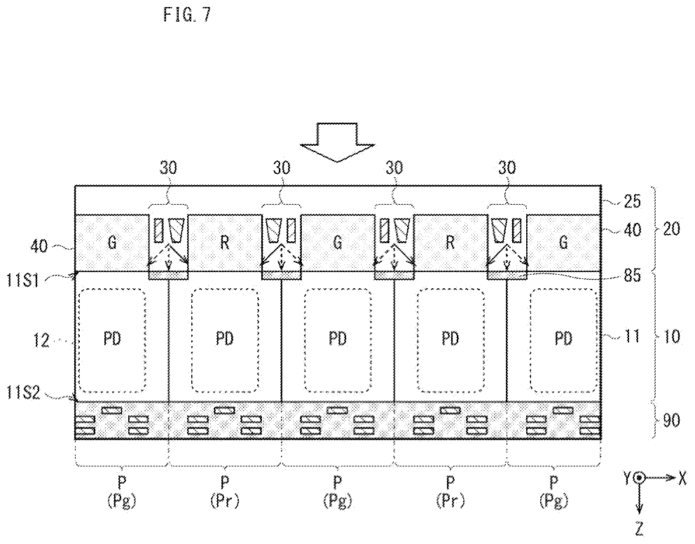

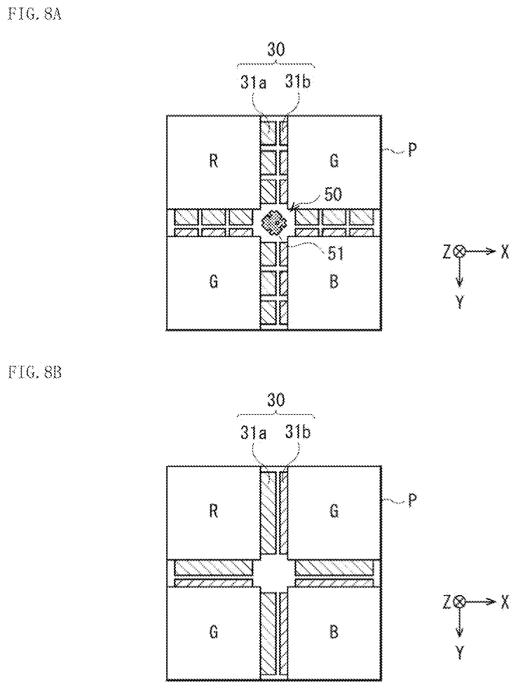

FIG. 6 is a diagram illustrating an example of a cross-sectional configuration of an imaging device 1 according to a first modification. FIG. 7 is a diagram illustrating another example of the cross-sectional configuration of the imaging device 1 according to the first modification. Like an example illustrated in FIG. 6, portions of the structures 31 (first structure 31a and second structure 31b) of the spectroscopic section 30 may be provided between adjacent color filters 40. Alternatively, as illustrated in FIG. 7 the whole structures 31 of the spectroscopic section 30 may be provided between the adjacent color filters 40. Also in these cases, it is possible to improve efficiency of collecting light onto the respective photoelectric conversion sections 12. In addition, this makes it possible to propagate unnecessary light to the light shielding section 85 among light incident on adjacent pixels P, and it is possible to suppress color mixing.

### (1-2. Second Modification)

FIG. 8A is a diagram illustrating an example of a planar configuration of an imaging device 1 according to a second modification. In the example illustrated in FIG. 8A, the imaging device 1 includes a spectroscopic section 50 provided in a central region surrounded by four pixels P, that is, among the adjacent pixels in oblique directions. The spectroscopic section 50 includes a structure. For example, as illustrated in FIG. 8A, the spectroscopic section 50 includes a fine lattice-shaped structure 51, and disperses light beams of the red (R), greed (G), and blue (B) wavelength bands included in incident light to the pixel Pr, pixel Pg, and pixel Pb, respectively.

The imaging device 1 according to the present modification includes the spectroscopic sections 30 and the spectroscopic sections 50, each of the spectroscopic sections 30 being provided on a boundary between pixels P that are adjacent in the horizontal direction or normal incidence for example, each of the spectroscopic sections 50 being provided on a boundary among pixels P that are adjacent in the oblique directions. This allows the spectroscopic sections 30 and the spectroscopic sections 50 to collect light and further improve efficiency of collecting light onto the photoelectric conversion sections 12 of the respective pixels.

It is to be noted that, as illustrated in FIG. 8B, the structures 31 (first structure 31a and second structure 31b in FIG. 8B) of the spectroscopic sections 30 may be continuously arranged or may be connected to each other.

### (1-3. Third Modification)

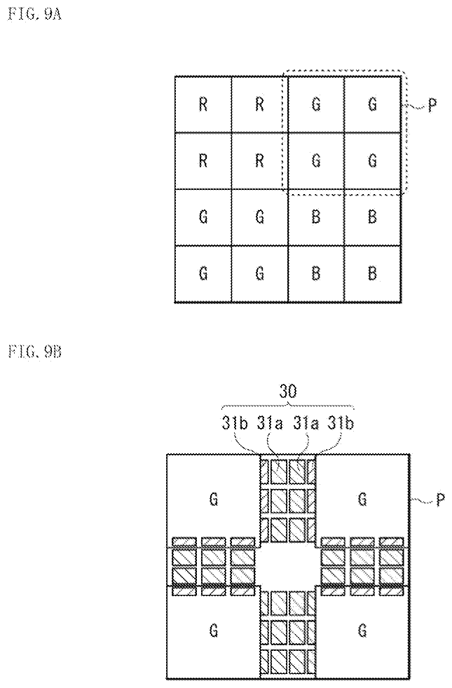

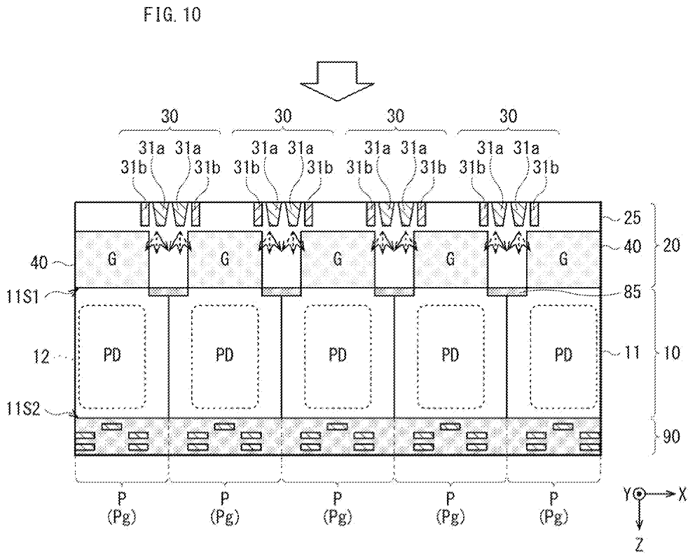

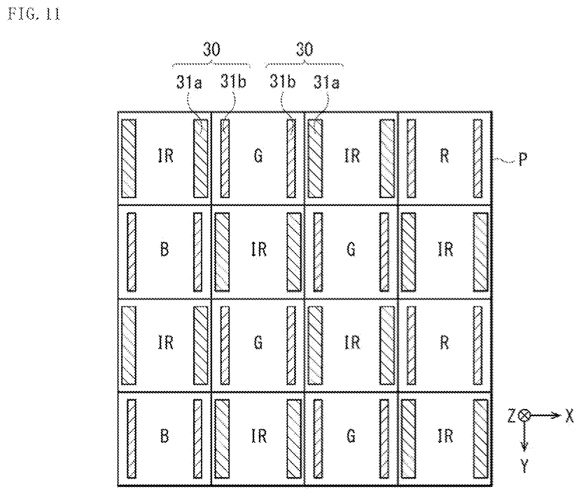

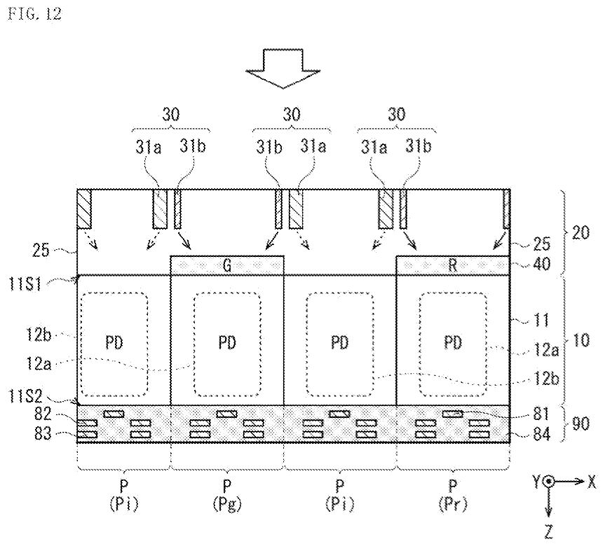

FIG. 9A is a diagram illustrating an example of a planar configuration of an imaging device 1 according to a third modification. A pixel section 100 of the imaging device 1 includes four pixels Pr, four pixels Pg, and four pixels Pb that are arranged on the basis of Bayer arrangement. FIG. 9B illustrates a planar configuration of the four pixels Pg illustrated in FIG. 9A. In addition, FIG. 10 is a diagram illustrating an example of a cross-sectional configuration of the imaging device 1 according to the third modification.

In FIG. 9B and FIG. 10, a spectroscopic section 30 includes two first structures 31a and two second structures 31b that are provided between adjacent pixels P of a same color. Between the adjacent pixels Pg, the two second structures 31b are arranged with the two first structures 31a interposed therebetween in the X-axis direction. A width of the first structure 31a in the X-axis direction is wider than a width of the second structure 31b in the X-axis direction.

In this case, as illustrated in FIG. 10, the spectroscopic section 30 is able to propagate the green (G) light among incident light, to color filters 40 and photoelectric conversions 12 of the pixels Pg arranged on both sides of the spectroscopic section 30. In addition, the spectroscopic section 30 is able to propagate the blue (B) light and the red (R) light among the incident light, to the waveguide 80 and the light shielding section 85. As described above, it is possible for the imaging device 1 according to the present modification to improve the efficiency of collecting light. In addition, it is also possible to propagate unnecessary light to the light shielding section 85, and to suppress color mixing.

### 2. Second Embodiment

Next, a second embodiment of the present disclosure will be described. Hereinafter, structural elements that are similar to the above-described embodiment will be denoted with the same reference signs as the above-described embodiment, and repeated description will be omitted appropriately.

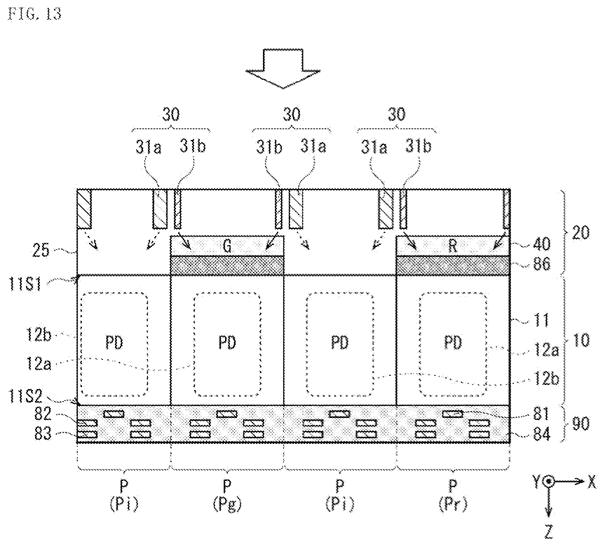

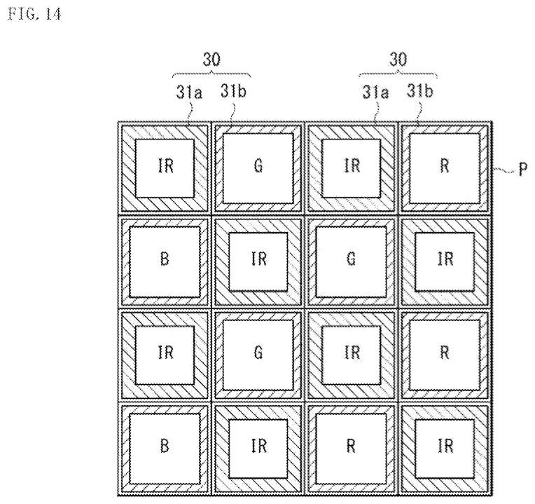

FIG. 11 is a diagram illustrating an example of a planar configuration of an imaging device 1 according to the second embodiment of the present disclosure. FIG. 12 is a diagram illustrating an example of a cross-sectional configuration of the imaging device 1. A spectroscopic section 30 includes a first structure 31a and a second structure 31b, and is provided on a boundary between adjacent pixels P.

For example, the first structure 31a has a size that is less than or equal to an infrared wavelength such as a size that is less than or equal to a near-infrared wavelength. For example, the second structure 31b has a size that is less than or equal to a visible wavelength. The size (cross-sectional area and width) of the first structure 31a is larger than the size of the second structure 31b. This allows the spectroscopic section 30 to cause the phase delay in such a manner that the incident light has different phase delays between a visible wavelength band and an infrared wavelength band, and this makes it possible to separate visible light and infrared light from the incident light.

The spectroscopic section 30 becomes able to cause light beams of the visible wavelength band and the infrared wavelength band to travel to different directions, among the incident light. In the example illustrated in FIG. 12, light of the green (G) wavelength band among the light incident on the spectroscopic section 30 travels from the spectroscopic section 30 toward the green (G) color filter 40 and a photoelectric conversion section 12a. In addition, light of the infrared wavelength band among the light incident on the spectroscopic section 30 travels from the spectroscopic section 30 toward a photoelectric conversion section 12b. In addition, light of the red (R) wavelength band travels from the spectroscopic section 30 toward the red (R) color filter 40 and a photoelectric conversion section 12a.

The pixel Pg including the photoelectric conversion section 12a receives and performs photoelectric conversion on the green (G) wavelength light and generates a pixel signal. The pixel Pr including the photoelectric conversion section 12a receives and performs photoelectric conversion on the red (R) wavelength light and generates a pixel signal. In addition, a pixel Pi including the photoelectric conversion section 12b receives and performs photoelectric conversion on the infrared (near-infrared) wavelength light and generates a pixel signal. The pixel Pb receives and performs photoelectric conversion on the blue (B) wavelength light and generates a pixel signal. This allows the imaging device 1 to generate an infrared image (NIR image) and a visible image by using the obtained pixel signals.

### Actions and Effects

The imaging device 1 according to the present embodiment includes the spectroscopic sections 30. The spectroscopic sections 30 each include the first structure 31a and the second structure 31b. The first structure 31a has a size that is less than or equal to the infrared wavelength. The second structure 31b has a size that is less than or equal to the visible wavelength.

The spectroscopic section 30 of the imaging device 1 includes the first structure 31a and the second structure 31b, and separates the visible wavelength light and the infrared wavelength light from the incident light. This makes it possible to simultaneously obtain pixel signals depending on amounts of visible light and a pixel signal depending on an amount of infrared light. It is possible to acquire the NIR image and the visible image.

Next, modifications of the present disclosure will be described. Hereinafter, structural elements that are similar to the above-described embodiment will be denoted with the same reference signs as the above-described embodiment, and repeated description will be omitted appropriately.

### (2-1. Fourth Modification)

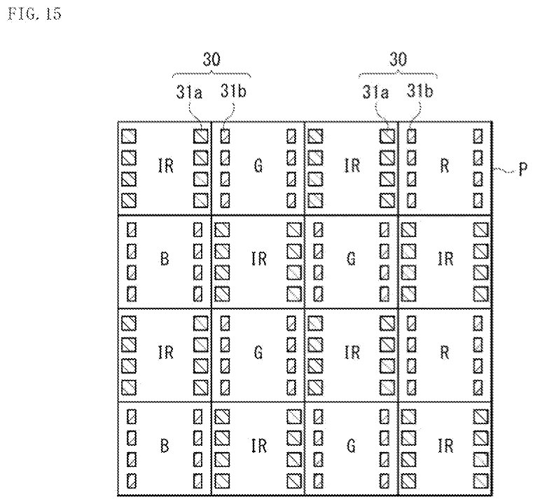

FIG. 13 is a diagram illustrating an example of a cross-sectional configuration of an imaging device 1 according to a fourth modification. The imaging device 1 according to the present modification includes a filter (IR-cut filter) 86 that blocks infrared light. In FIG. 13, the respective filter 86 are provided between the color filter 40 and the photoelectric conversion section 12a of the pixel Pg, and between the color filter 40 and the photoelectric conversion section 12a of the pixel Pr. In addition, in a similar way, the filter 86 is provided between the color filter 40 and the photoelectric conversion section 12a of the pixel Pb.

According to the present modification, it is possible to prevent infrared light from leaking to the pixels P (pixel Pr, pixel Pg, and Pixel Pb) that receive and perform photoelectric conversion on visible light. This makes it possible to improve color reproducibility by the RGB pixel signals.

### (2-2. Fifth Modification)

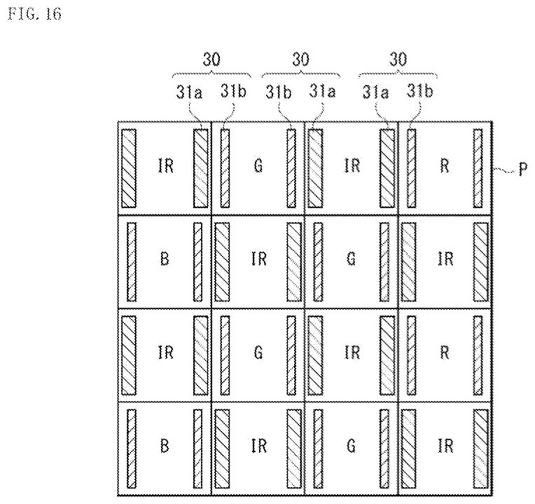

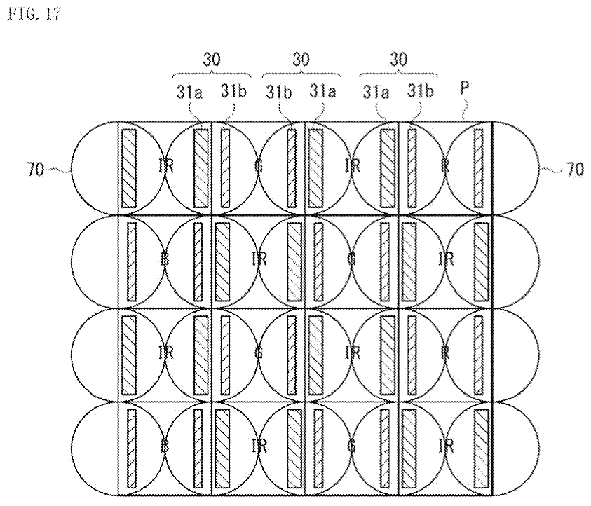

In the above embodiments, the configuration examples of the spectroscopic sections 30 including the structures 31 have been described. However, the shapes, number, and the like of the structures 31 are not limited to the examples illustrated in the drawings. FIG. 14 and FIG. 15 are diagrams each illustrating an example of a planar configuration of an imaging device 1 according to a fifth modification.

For example, as illustrated in FIG. 14, the first structure 31a and the second structure 31b may surround the photoelectric conversion section 12 or the color filter 40 of the pixel P. Alternatively, for example, as illustrated in FIG. 15, a plurality of the first structures 31a and a plurality of the second structures 31b may be discretely arranged on a boundary between adjacent pixels P.

### (2-3. Sixth Modification)

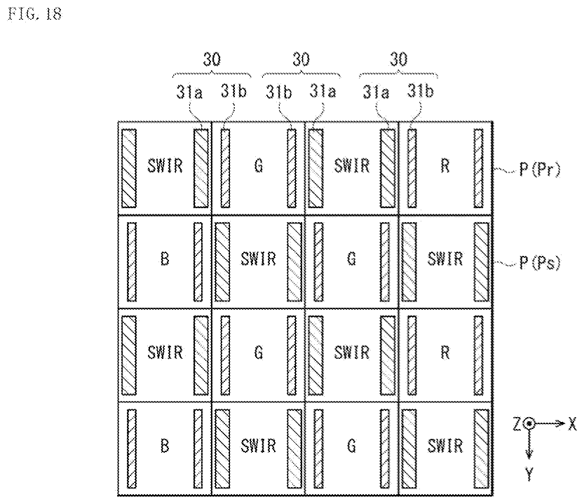

FIG. 16 and FIG. 17 are diagrams each illustrating an example of a planar configuration of an imaging device 1 according to a sixth modification. In a pixel section 100 of the imaging device 1, the pixels Pr, pixels Pg, and pixels Pb that receive the visible light and the pixels Pi that receive the infrared light may be arranged as illustrated in FIG. 16.

As illustrated in FIG. 17, lens sections (on-chip lenses) 70 that collect light may be provided above the respective spectroscopic sections 30. The lens sections 70 may be arranged in such a manner that a center of each of the lens sections 70 is positioned on a boundary between adjacent pixels P. In this case, this makes it possible to collect much light onto the spectroscopic section 30 and efficiently disperse light.

### (2-4. Seventh Modification)

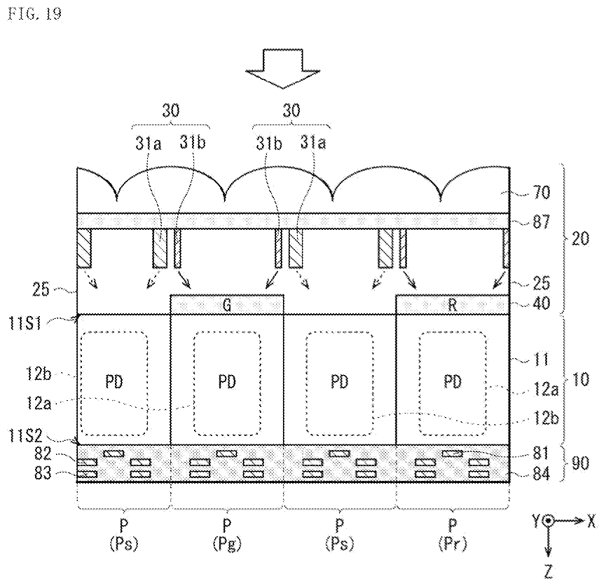

FIG. 18 is a diagram illustrating an example of a planar configuration of an imaging device 1 according to a seventh modification. FIG. 19 is a diagram illustrating an example of a cross-sectional configuration of the imaging device 1 according to the seventh modification. As illustrated in FIG. 18, the imaging device 1 according to the present modification includes pixels Ps each of which receives light of a shortwave infrared (SWIR) wavelength band. As illustrated in FIG. 19, a light guiding section 20 includes the lens section 70 that collects light, and a filter (NIR-cut filter) 87 that blocks near-infrared light. The filter 87 is provided above the spectroscopic section 30.

In the example illustrated in FIG. 19, the filter 87 is provided between the lens section 70 and the spectroscopic section 30. For example, the filter 87 includes a dielectric multilayer film. The filter 87 blocks near-infrared light and transmits visible light and shortwave infrared light among incident light. It is to be noted that the lens section 70 may be omitted from the imaging device 1.

The first structure 31a has a size that is less than or equal to a shortwave infrared wavelength, for example. For example, the second structure 31b has a size that is less than or equal to a visible wavelength. The size (cross-sectional area and width) of the first structure 31a is larger than the size of the second structure 31b. In this case, this allows the spectroscopic section 30 to cause the phase delay in such a manner that the incident light has different phase delays between the visible wavelength band and the shortwave infrared wavelength band, and this makes it possible to separate visible light and shortwave infrared light from the incident light.

In the example illustrated in FIG. 19, light of the green (G) wavelength band among the light incident on the spectroscopic section 30 through the lens section 70 and the filter 87 travels from the spectroscopic section 30 toward the green (G) color filter 40 and the photoelectric conversion section 12a. In addition, light of the shortwave infrared wavelength band among the light incident on the spectroscopic section 30 travels from the spectroscopic section 30 toward a photoelectric conversion section 12b. Light of the red (R) wavelength band travels from the spectroscopic section 30 toward the red (R) color filter 40 and the photoelectric conversion section 12a. It is to be noted that the photoelectric conversion section 12b that receives the shortwave infrared light may be formed by using quantum dots, a compound semiconductor (such as InGaAs), or the like, for example. In addition, the photoelectric conversion section 12b may include material such as germanium (Ge) or silicon-germanium (SiGe).

The pixel Pg including the photoelectric conversion section 12a receives and performs photoelectric conversion on the green (G) wavelength light and generates a pixel signal. The pixel Pr receives and performs photoelectric conversion on the red (R) wavelength light and generates a pixel signal. It is to be noted that the pixel Pb receives and performs photoelectric conversion on the blue (B) wavelength light and generates a pixel signal. In addition, the pixel Ps including the photoelectric conversion section 12b receives and performs photoelectric conversion on the shortwave infrared wavelength light and generates a pixel signal. This allows the imaging device 1 according to the present modification to generate a shortwave infrared image (SWIR image) and a visible image by using the obtained pixel signals.

The lens sections 70 are arranged in such a manner that a center of each of the lens sections 70 is positioned on a boundary between adjacent pixels P. This makes it possible to collect much light onto the spectroscopic section 30 and efficiently disperse light. It becomes possible to collect light from an area wider than a single pixel onto the spectroscopic section 30 and improve sensitivity to the incident light.

### 3. Application Example

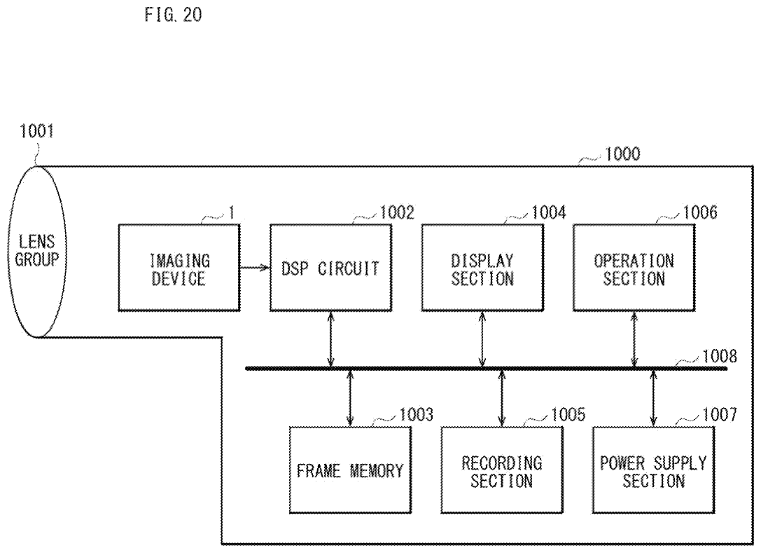

The above-described imaging device 1 or the like are applicable to any type of electronic apparatus having an imaging function, such as a camera system of a digital still camera or a video camera, or a mobile phone having an imaging function. FIG. 20 illustrates a schematic configuration of an electronic apparatus 1000.

The electronic apparatus 1000 includes, for example, a lens group 1001, the imaging device 1, a digital signal processor (DSP) circuit 1002, a frame memory 1003, a display section 1004, a recording section 1005, an operation section 1006, and a power supply section 1007. They are coupled to each other through a bus line 1008.

The lens group 1001 takes in incident light (image light) from a subject and forms an image on the imaging surface of the imaging device 1. The imaging device 1 converts the amount of incident light formed as an image on the imaging surface by the lens group 1001 into electric signals in units of pixels and supplies the DSP circuit 1002 with the electric signals as pixel signals.

The DSP circuit 1002 is a signal processing circuit that processes a signal supplied from the imaging device 1. The DSP circuit 1002 outputs image data that is obtained by processing the signals from the imaging device 1. The frame memory 1003 temporarily holds the image data processed by the DSP circuit 1002 in units of frames.

The display section 1004 includes, for example, a panel-type display device such as a liquid crystal panel or an organic electroluminescence (EL) panel and records the image data of a moving image or a still image captured by the imaging device 1 in a recording medium such as a semiconductor memory or a hard disk.

The operation section 1006 outputs an operation signal for a variety of functions of the electronic apparatus 1000 in accordance with an operation by a user. The power supply section 1007 appropriately supplies the DSP circuit 1002, the frame memory 1003, the display section 1004, the recording section 1005, and the operation section 1006 with various kinds of power for operations of these supply targets.

### 4. Further Application Example

### (Example of Application to Mobile Object)

The technology according to the present disclosure (present technology) is applicable to various products. For example, the technology according to the present disclosure may be implemented as a device that is installed on any kind of mobile objects including vehicles, electric vehicles, hybrid electric vehicles, motorcycles, bicycles, personal mobilities, airplanes, drones, ships, robots, and the like.

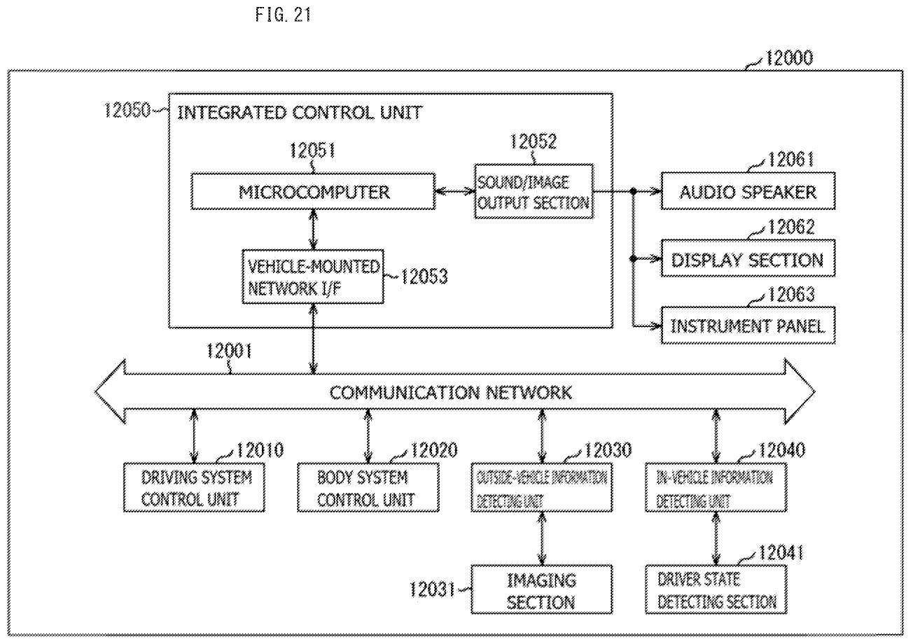

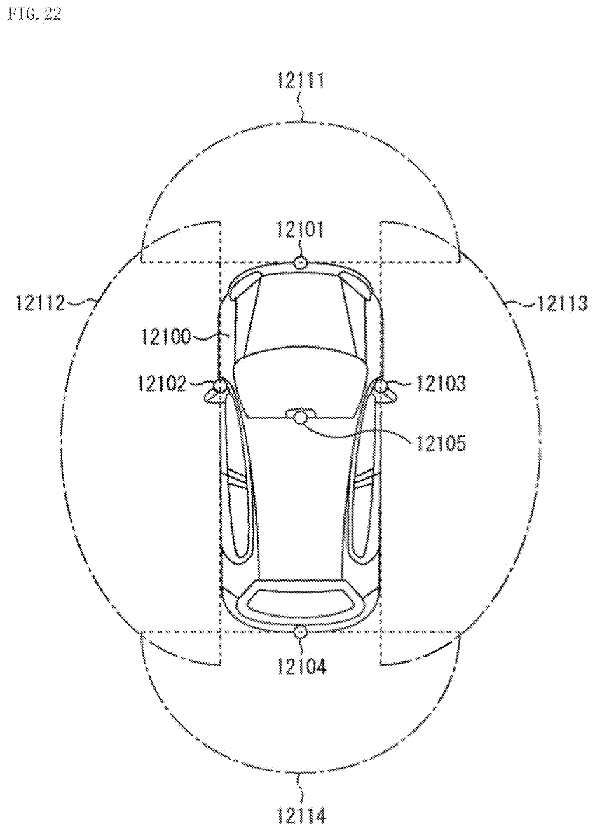

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the mobile object control system to which the technology according to the present disclosure is applicable has been described above. The technology according to the present disclosure is applicable to the imaging section 12031 among the above-described structural elements. Specifically, for example, the imaging device 1 is applicable to the imaging section 12031. It is possible to obtain a high-resolution captured image with less noises by applying the technology according to the present disclosure to the imaging section 12031. Therefore, it is possible to perform high-precision control utilizing the captured image in the mobile object control system.

### (Example of Application to Endoscopic Surgery System)

The technology according to the present disclosure (present technology) is applicable to various products. For example, the technology according to the present disclosure is applicable to an endoscopic surgery system.

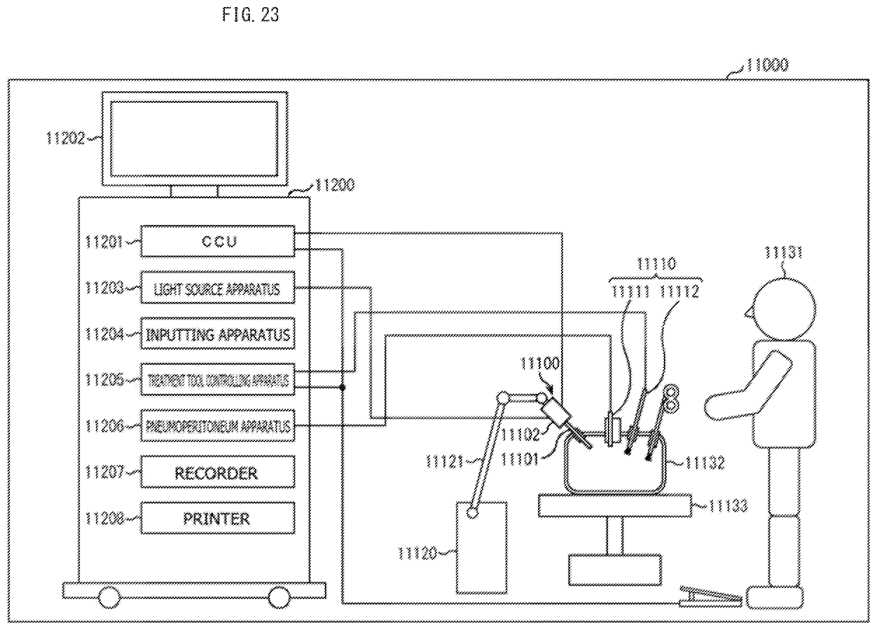

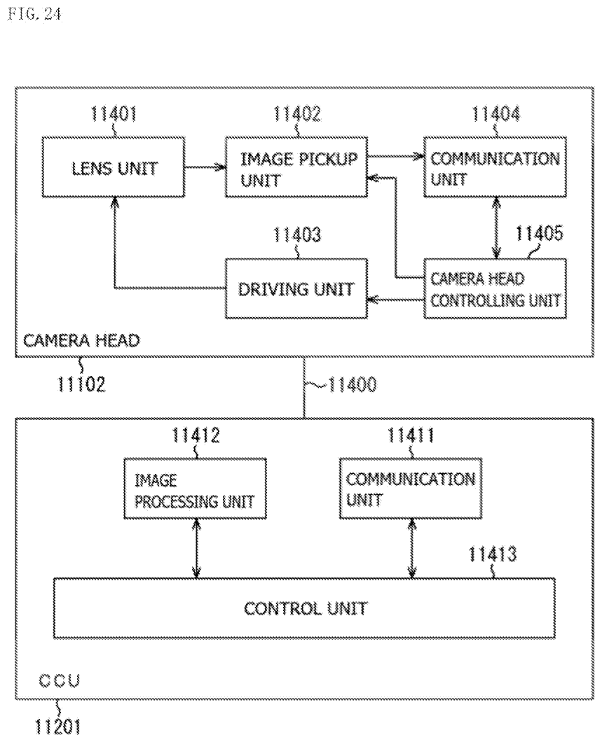

FIG. 23 is a view depicting an example of a schematic configuration of an endoscopic surgery system to which the technology according to an embodiment of the present disclosure (present technology) can be applied.

In FIG. 23, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 24 is a block diagram depicting an example of a functional configuration of the camera head 11102 and the CCU 11201 depicted in FIG. 23.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure is applicable has been described above. The technology according to the present disclosure is favorably applicable to the image pickup unit 11402 provided to the camera head 11102 of the endoscope 11100 among the above-described components. The application of the technology according to the present disclosure to the image pickup unit 11402 makes it possible to sensitize the image pickup unit 11402 and provide the high-resolution endoscope 11100.

The present technology has been described above with reference to the embodiments, modifications, application examples, and further application examples. However, the present technology is not limited thereto, and various kinds of modifications thereof can be made. For example, the above modifications have been described as the modifications of the embodiments. In addition, structural elements according to the respective modifications can be used in combination as appropriate. For example, the present disclosure is not limited to back-illuminated image sensors, but may be applicable to front-illuminated image sensors.

It is to be noted that the effects described herein are only for illustrative purposes and there may be other effects. In addition, the present technology may be configured as follows.

(1)

An imaging device including:
a first pixel including a first photoelectric conversion section that selectively receives first wavelength light included in a first wavelength band and performs photoelectric conversion on the first wavelength light;
a second pixel including a second photoelectric conversion section that selectively receives second wavelength light included in a second wavelength band and performs photoelectric conversion of the second wavelength light, the second pixel being adjacent to the first pixel; and
a spectroscopic section including a structure having a size less than or equal to a wavelength of incident light, the spectroscopic section being provided on a boundary between the first pixel and the second pixel, the spectroscopic section separating the first wavelength light and the second wavelength light from the incident light.
   (2)

The imaging device according to (1), including
a transparent layer including the spectroscopic section, in which
the structure has a refractive index that is higher than a refractive index of the transparent layer.
   (3)

The imaging device according to (1) or (2), including
a light guiding section that guides light, the light guiding section being provided on the boundary between the first pixel and the second pixel, in which
the spectroscopic section is provided above the light guiding section, and
the light guiding section guides light having passed through the spectroscopic section.
   (4)

The imaging device according to any one of (1) to (3), in which
the first pixel includes a first filter that transmits light of the first wavelength band,
the second pixel includes a second filter that transmits light of the second wavelength band,
the first photoelectric conversion section receives the first wavelength light having passed through the first filter, and
the second photoelectric conversion section receives the second wavelength light having passed through the second filter.
   (5)

The imaging device according to any one of (1) to (4), in which a plurality of the structures is provided so as to surround each of the first filter and the second filter.

(6)

The imaging device according to any one of (1) to (5), in which
the spectroscopic section includes a first structure and a second structure having different sizes as the structures, and
the spectroscopic section guides the first wavelength light among the incident light toward the first filter and guides the second wavelength light among the incident light toward the second filter.
   (7)

The imaging device according to any one of (1) to (6), in which the spectroscopic section guides a third wavelength light being included in a third wavelength band of the incident light toward a gap between the first filter and the second filter.

(8)

The imaging device according to (1), in which the spectroscopic section includes the first structure and the second structure as the structures, and separates the first wavelength light and the second wavelength light from the incident light, the first wavelength light being visible wavelength light, the second wavelength light being infrared wavelength light.

(9)

The imaging device according to (7) or (8), in which
the first structure has a size less than or equal to a visible wavelength, and
the second structure has a size less than or equal to an infrared wavelength and larger than the first structure.
   (10)

The imaging device according to any one of (7) to (9), in which
the first structure is provided on a side of the first pixel,
the second structure is provided on a side of the second pixel, and
the spectroscopic section guides the first wavelength light among the incident light toward the first photoelectric conversion section and guides the second wavelength light among the incident light toward the second photoelectric conversion section, the first wavelength light being the visible wavelength light, the second wavelength light being the infrared wavelength light.

The present application claims the benefit of Japanese Priority Patent Application JP2021-129693 filed with the Japan Patent Office on Aug. 6, 2021, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

What is claimed is:

1. An imaging device, comprising:
a first pixel including a first photoelectric conversion section that selectively receives first wavelength light included in a first wavelength band and performs photoelectric conversion of the first wavelength light;
a second pixel including a second photoelectric conversion section that selectively receives second wavelength light included in a second wavelength band and performs photoelectric conversion of the second wavelength light, the second pixel being adjacent to the first pixel; and
a spectroscopic section including a structure having a size less than or equal to a wavelength of incident light, the spectroscopic section being provided on a boundary between the first pixel and the second pixel, the spectroscopic section separating the first wavelength light and the second wavelength light from the incident light.

2. The imaging device according to claim 1, comprising
a transparent layer including the spectroscopic section, wherein
the structure has a refractive index higher than a refractive index of the transparent layer.

3. The imaging device according to claim 1, comprising
a light guiding section that guides light, the light guiding section being provided on the boundary between the first pixel and the second pixel, wherein
the spectroscopic section is provided above the light guiding section, and
the light guiding section guides light having passed through the spectroscopic section.

4. The imaging device according to claim 1, wherein the first pixel includes a first filter that transmits light of the first wavelength band,
the second pixel includes a second filter that transmits light of the second wavelength band,
the first photoelectric conversion section receives the first wavelength light having passed through the first filter, and
the second photoelectric conversion section receives the second wavelength light having passed through the second filter.

5. The imaging device according to claim 4, wherein a plurality of the structures is provided so as to surround each of the first filter and the second filter.

6. The imaging device according to claim 4, wherein
the spectroscopic section includes a first structure and a second structure having different sizes as the structures, and
the spectroscopic section guides the first wavelength light among the incident light toward the first filter and guides the second wavelength light among the incident light toward the second filter.

7. The imaging device according to claim 6, wherein the spectroscopic section guides a third wavelength light being included in a third wavelength band of the incident light toward a gap between the first filter and the second filter.

8. The imaging device according to claim 1, wherein the spectroscopic section includes the first structure and the second structure as the structures, and separates the first wavelength light and the second wavelength light from the incident light, the first wavelength light being visible wavelength light, the second wavelength light being infrared wavelength light.

9. The imaging device according to claim 8, wherein
the first structure has a size less than or equal to a visible wavelength, and
the second structure has a size less than or equal to an infrared wavelength and larger than the first structure.

10. The imaging device according to claim 9, wherein
the first structure is provided on a side of the first pixel,
the second structure is provided on a side of the second pixel, and
the spectroscopic section guides the first wavelength light among the incident light toward the first photoelectric conversion section and guides the second wavelength light among the incident light toward the second photoelectric conversion section, the first wavelength light being the visible wavelength light, the second wavelength light being the infrared wavelength light.
